(19) United States
(12) Patent Application Publication
(10) Pub. No.: US 2017/0342273 A1
(43) Pub. Date: Nov. 30, 2017

(54) Silica Fillers and Methods of Making Same

(71) Applicant: Georgia Tech Research Corporation, Atlanta, GA (US)

(72) Inventors: Chia-Chi Tuan, Atlanta, GA (US); Kyoung-Sik Moon, Atlanta, GA (US); Ching Ping Wong, Atlanta, GA (US)

(21) Appl. No.: 15/608,508

(22) Filed: May 30, 2017

Related U.S. Application Data
(60) Provisional application No. 62/342,232, filed on May 27, 2016.

(51) Int. Cl. C09C 1/30; B01J 2/00; C08K 9/08; H01L 23/29

(52) U.S. Cl. CPC C09C 1/3081; H01L 23/295; B01J 2/006; C08K 9/08; C01P 2006/32

(57) ABSTRACT

An exemplary embodiment of the present invention provides a filler comprising a silica core, a first layer in communication with the core, and a second layer in communication with the first layer. The presence of the second layer can decrease the coefficient of thermal expansion, decrease the composite modulus, and increase the glass transition temperature of the modulus as compared to fillers without a second layer.

### CROSS-REFERENCE TO RELATED APPLICATIONS

This application claims the benefit of U.S. Provisional Application Ser. No. 62/342,232, filed on May 27, 2016, which is incorporated herein by reference in its entirety as if fully set forth below.

### TECHNICAL FIELD OF THE INVENTION

The various embodiments of the present disclosure relate generally to silica fillers and methods of making the same. More particularly, the various embodiments of the present invention are directed to double-layer coated silica fillers that exhibit improved thermal expansion and transition temperatures.

### BACKGROUND OF THE INVENTION

Due to the development trend in microelectronic packaging towards large dies and three-dimensional packaging, new underfill materials are in demand. For example, in modern packaging technologies, underfill with ultra-low coefficient of thermal expansion (“CTE”), e.g., less than 25 ppm/K, and low modulus are highly desirable for low stress material. Unfortunately, conventional underfills see a strong coupling between the thermomechanical and mechanical properties, i.e., increasing the loading of silica fillers reduces the CTE and conversely increases the modulus. In addition to these aforementioned property requirements, the size of fillers should be on the nanometer scale, such that the material could offer (a) flowability into the fine-pitch, low profile packages in capillary underfill, (b) reduction in filler trapping in no-flow underfill, and (c) high transparency in wafer-level underfill. Nano-fillers, however, also come with larger surface area than micro-fillers and a poor silica-polymer interface, which results from imperfect surface treatments on the filler. Although epoxy-silane molecules are commonly used to modify the silica surfaces for underfills, such a procedure results in unsatisfactory surface interactions, as indicated by a decrease in the glass transition temperature of these conventional composite materials.

Therefore, there is a desire for improved fillers and methods of making the same that lead to a decreased coefficient of thermal expansion, a decrease in the modulus, and an increase in the glass transition temperature. Various embodiments of the present invention address these desires.

### BRIEF SUMMARY OF THE INVENTION

The present invention relates to silica fillers and methods of making the same. An exemplary embodiment of the present invention provides a filler comprising a silica core, a first layer, and a second layer. The first layer can be in communication with the core and can comprise a first material. The second layer can be in communication with the first layer and can comprise a second material different than the first material. The second layer can decrease the coefficient of thermal expansion of the filler and decrease the composite modulus of the filler as compared to a filler without the second layer.

In some embodiments of the present invention, the first layer comprises silane.

In some embodiments of the present invention, the first layer comprises amine-containing silane.

In some embodiments of the present invention, the second layer comprises polysiloxane.

In some embodiments of the present invention, the filler comprises an amorphous silica nanosphere.

In some embodiments of the present invention, the second layer is covalently bonded to the first layer.

In some embodiments of the present invention, the second layer increases the glass transition temperature of the filler as compared to a filler without the second layer.

In some embodiments of the present invention, the filler has a coefficient of thermal expansion between about 20 ppm/K and about 40 ppm/K.

In some embodiments of the present invention, the filler has a coefficient of thermal expansion between about 25 ppm/K and about 35 ppm/K.

In some embodiments of the present invention, the filler has a coefficient of thermal expansion of about 25 ppm/K to about 30 ppm/K.

In some embodiments of the present invention, the first layer is present in the filler at about 0.75-1.5 wt. %.

In some embodiments of the present invention, the second layer is present in the filler at about 0.5-1.0 wt. %.

Another embodiment of the present invention provides a method of making a making a filler comprising a silica core layer, a first layer, and a second layer. The method comprises coating the silica core with the first layer and coating the first layer with the second layer. Coating the first layer with the second layer can decrease the coefficient of thermal expansion of the filler and decrease the composite modulus of the filler.

In some embodiments of the present invention, coating the first layer with the second layer results in covalent bonds between the first and second layer.

In some embodiments of the present invention, coating the first layer with the second layer increases the glass transition temperature of the filler.

Another embodiment of the present invention provides a filler comprising an amorphous silica nanosphere core, a first layer in communication with the core, and a second layer covalently bonded to the first layer. The first layer comprises silane. The second layer comprises polysiloxane. The filler can have a coefficient of thermal expansion from about 20 ppm/K to about 40 ppm/K, from about 20 ppm/K to about 30 ppm/K, or from about 25 ppm/K to about 30 ppm/K.

These and other aspects of the present invention are described in the Detailed Description of the Invention below and the accompanying figures. Other aspects and features of embodiments of the present invention will become apparent to those of ordinary skill in the art upon reviewing the following description of specific, exemplary embodiments of the present invention in concert with the figures. While features of the present invention may be discussed relative to certain embodiments and figures, all embodiments of the present invention can include one or more of the features discussed herein. Further, while one or more embodiments may be discussed as having certain advantageous features, one or more of such features may also be used with the various embodiments of the invention discussed herein. In similar fashion, while exemplary embodiments may be discussed below as device, system, or method embodiments, it is to be understood that such exemplary embodiments can be implemented in various devices, systems, and methods of the present invention.

### BRIEF DESCRIPTION OF THE DRAWINGS

The following Detailed Description of the Invention is better understood when read in conjunction with the appended drawings. For the purposes of illustration, there is shown in the drawings exemplary embodiments, but the subject matter is not limited to the specific elements and instrumentalities disclosed.

FIG. 1 provides a conventional filler.

FIG. 2 provides a filler, in accordance with an exemplary embodiment of the present invention.

FIG. 3 provides a plot of heat flow versus temperature a filler in accordance with an exemplary embodiment of the present invention.

FIG. 4 provides a plot of weight versus temperature for conventional fillers and a filler in accordance with an exemplary embodiment of the present invention.

FIG. 5A provides a photograph of a conventional filler.

FIG. 5B provides a photograph of a filler, in accordance with an exemplary embodiment of the present invention.

FIG. 6 provides a photograph of a filler, in accordance with an exemplary embodiment of the present invention.

FIG. 7 provides a plot of heat flow versus temperature for conventional filler and fillers in accordance with exemplary embodiments of the present invention.

FIG. 8 provides a plot of storage modulus versus temperature for conventional fillers and a filler in accordance with exemplary embodiments of the present invention.

FIG. 9 provides a plot of coefficient of thermal expansions for conventional fillers and a filler in accordance with exemplary embodiments of the present invention.

### DETAILED DESCRIPTION OF THE INVENTION

To facilitate an understanding of the principles and features of the present invention, various illustrative embodiments are explained below. The components, steps, and materials described hereinafter as making up various elements of the invention are intended to be illustrative and not restrictive. Many suitable components, steps, and materials that would perform the same or similar functions as the components, steps, and materials described herein are intended to be embraced within the scope of the invention. Such other components, steps, and materials not described herein can include, but are not limited to, similar components or steps that are developed after development of the invention.

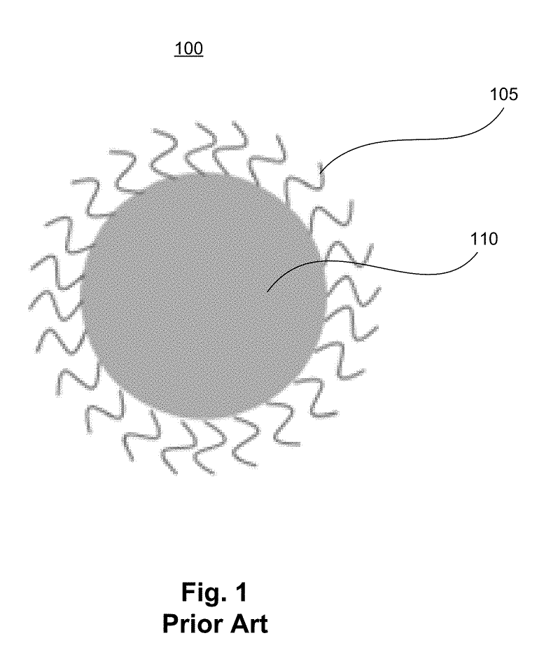

As shown in FIG. 1, conventional fillers comprised a silica core 110 and a first layer 105. As discussed above, however, these conventional fillers resulted in poor thermo-mechanical characteristics, including lower storage modulus, lower coefficients of thermal expansion, and lower glass transition temperatures. The inventors, however, discovered that by adding a second layer to these conventional fillers, the resulting fillers exhibited much more desirable thermo-mechanical properties.

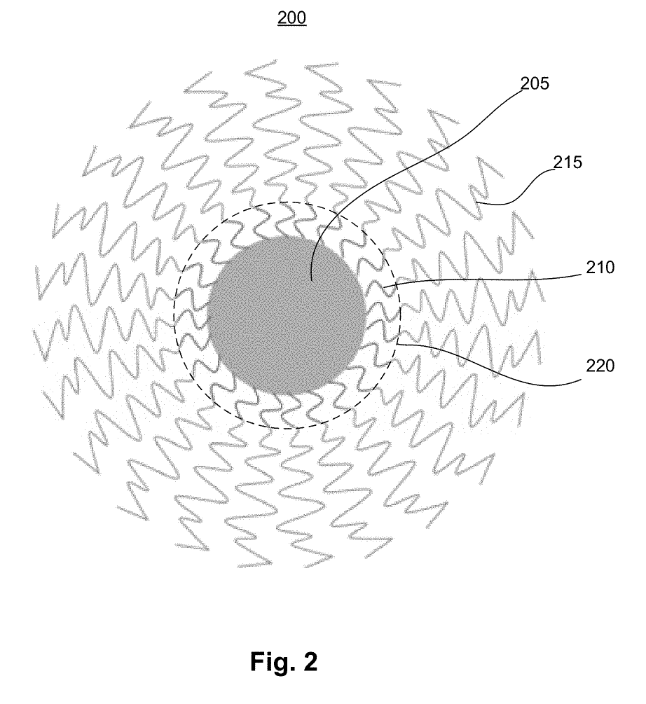

As shown in FIG. 2, an exemplary embodiment of the present invention provides a filler comprising a core 205, a first layer 210, and a second layer 215. The dotted line 220 is shown for demonstrative purposes only to demarcate between the first layer 210 and the second layer 215, but should not be interpreted to represent any physical layer/surface. In come embodiments, the core comprises silica. The core can be in the form of a fiber, e.g., a silica fiber. In some embodiments, the core is a nanosphere. In some embodiments, the core is amorphous. In some embodiments, the first layer comprises a first material. In some embodiments the first layer comprises silane. In some embodiments, the first layer can comprise an amine-containing silane. In some embodiments, the first layer comprises a short-chain coupling molecule having reactive groups toward silica and the second layer. In some embodiments, the first layer comprises chemical groups including, but not limited to, silanol, hydroxyl, epoxide, carboxylic groups, and the like.

In some embodiments, the second layer comprises a second material different than the first material of the first layer. In some embodiments, the second layer comprises polysiloxane. In some embodiments, the second layer comprises a rubber. In some embodiments, the second layer comprises a polymer chain with a number of monomer units larger than four. In some embodiments, the second layer comprises one or more soft segments, including, but not limited to, polyurethane, polybutadiene, polysiloxane, polyisoprene, and the like. In some embodiments, the polymer chain of the second layer comprises functional groups, including but not limited to, carboxylic acid, thiocarboxylic acid, epoxide, hydroxyl, silanol, amino, mercapto groups, and the like. In some embodiments, the second layer comprises a material that is chemically reactive to the first layer and/or the polymer matrix used in the composite material.

As shown in FIG. 2, the first layer can be in communication with, i.e., adjacent to, the with core, and the second layer can be in communication, i.e., adjacent to, the first layer. In some embodiments, the communication between the first and second layer can result from covalent bonding between the first and second layers.

The addition of the second layer to the filler can provide superior thermo-mechanical properties to the filler than would occur without the second layer. In some embodiments, the second layer decreases the composite/storage modulus of the filler as compared to a filler without the second layer. In some embodiments, the second layer increases the glass transition temperature of the filler as compared to a filler without the second layer.

In some embodiments of the present invention, the second layer decreases the coefficient of thermal expansion of the filler as compared to a filler without the second layer. In some embodiments, the filler has a coefficient of thermal expansion of less than 50 ppm/K. In some embodiments, the filler has a coefficient of thermal expansion of less than 40 ppm/K. In some embodiments, the filler has a coefficient of thermal expansion of less than 35 ppm/K. In some embodiments, the filler has a coefficient of thermal expansion of less than 30 ppm/K. In some embodiments, the filler has a coefficient of thermal expansion of less than 25 ppm/K. In some embodiments, the filler has a coefficient of thermal expansion of less than 20 ppm/K. In some embodiments, the filler has a coefficient of thermal expansion of between 20 ppm/K and 50 ppm/K. In some embodiments, the filler has a coefficient of thermal expansion of between 20 ppm/K and 40 ppm/K. In some embodiments, the filler has a coefficient of thermal expansion of between 20 ppm/K and 35 ppm/K. In some embodiments, the filler has a coefficient of thermal expansion of between 20 ppm/K and 30 ppm/K. In some embodiments, the filler has a coefficient of thermal expansion of between 25 ppm/K and 50 ppm/K. In some embodiments, the filler has a coefficient of thermal expansion of between 25 ppm/K and 40 ppm/K. In some embodiments, the filler has a coefficient of thermal expansion of between 25 ppm/K and 35 ppm/K. In some embodiments, the filler has a coefficient of thermal expansion of between 25 ppm/K and 30 ppm/K. In some embodiments, the filler has a coefficient of thermal expansion of between 28 ppm/K and 30 ppm/K. In some embodiments, the filler has a coefficient of thermal expansion of about 29 ppm/K.

The first and second layers can be present in the filler at varying amounts by weight percent, in accordance with various embodiments of the present invention. In some embodiments, the first layer is present in the filler at about 0.75-1.5 wt. %. In some embodiments, the first layer is present in the filler at less than about 5.0 wt. %. In some embodiments, the first layer is present in the filler at less than about 4.0 wt. %. In some embodiments, the first layer is present in the filler at less than about 3.0 wt. %. In some embodiments, the first layer is present in the filler at less than about 2.0 wt. %. In some embodiments, the first layer is present in the filler at less than about 1.5 wt. %. In some embodiments, the first layer is present in the filler at greater than about 0.1 wt. %. In some embodiments, the first layer is present in the filler at greater than about 0.25 wt. %. In some embodiments, the first layer is present in the filler at greater than about 0.5 wt. %. In some embodiments, the first layer is present in the filler at greater than about 0.75 wt. %. In some embodiments, the first layer is present in the filler at greater than about 1.0 wt. %.

In some embodiments, the second layer is present in the filler at about 0.5-1.0 wt. %. In some embodiments, the second layer is present in the filler at less than about 5.0 wt. %. In some embodiments, the second layer is present in the filler at less than about 4.0 wt. %. In some embodiments, the second layer is present in the filler at less than about 3.0 wt. %. In some embodiments, the second layer is present in the filler at less than about 2.0 wt. %. In some embodiments, the second layer is present in the filler at less than about 1.0 wt. %. In some embodiments, the second layer is present in the filler at greater than about 0.1 wt. %. In some embodiments, the second layer is present in the filler at greater than about 0.25 wt. %.In some embodiments, the second layer is present in the filler at greater than about 0.5 wt. %.In some embodiments, the second layer is present in the filler at greater than about 0.75 wt. %. In some embodiments, the second layer is present in the filler at greater than about 1.0 wt. %.

Another embodiment of the present invention provides a method of making a making a filler comprising a core 205, a first layer 210, and a second layer 215. The method comprises coating the core 205 with the first layer 210 and coating the first layer 210 with the second layer 215. Coating the first layer 210 with the second layer 215 can lead to the improved thermo-mechanical properties discussed above. In some embodiments of the present invention, coating the first layer with the second layer results in covalent bonds between the first and second layer.

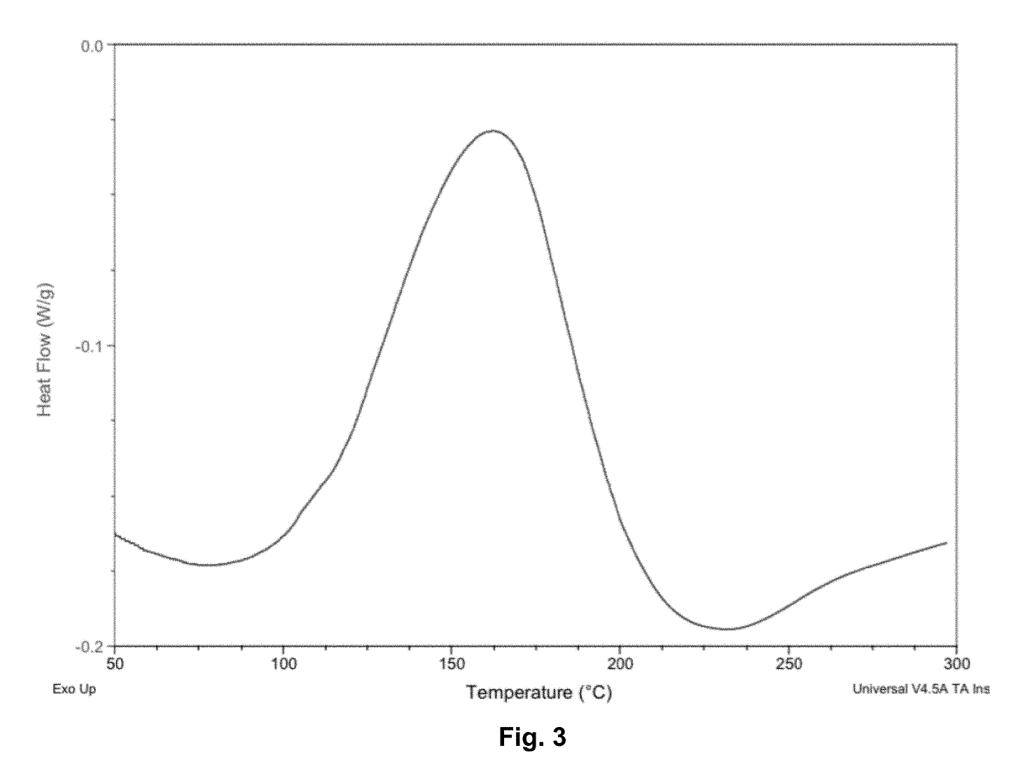

FIGS. 3-9 illustrate some of the improved thermo-mechanical properties provided by exemplary embodiments of the present invention as compared to certain conventional fillers. FIG. 3 illustrates how a silane-functionalized silica filler reacts with polysiloxane surface modifier under moderate heating.

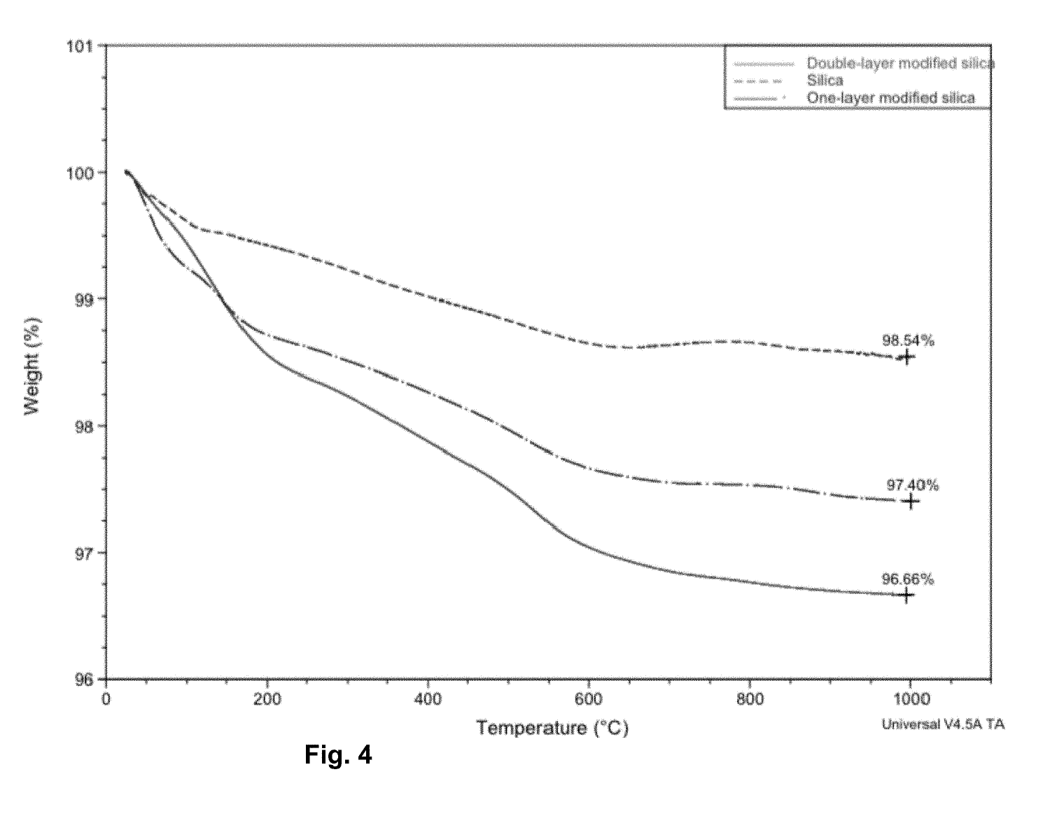

FIG. 4 plots weight % versus temperature for a double-layer modified silica in accordance with an embodiment of the present invention, wherein silane is present in about 1.14 wt. % and polysiloxane is present in about 0.74 wt. %, versus conventional silica and single-layer modified silica.

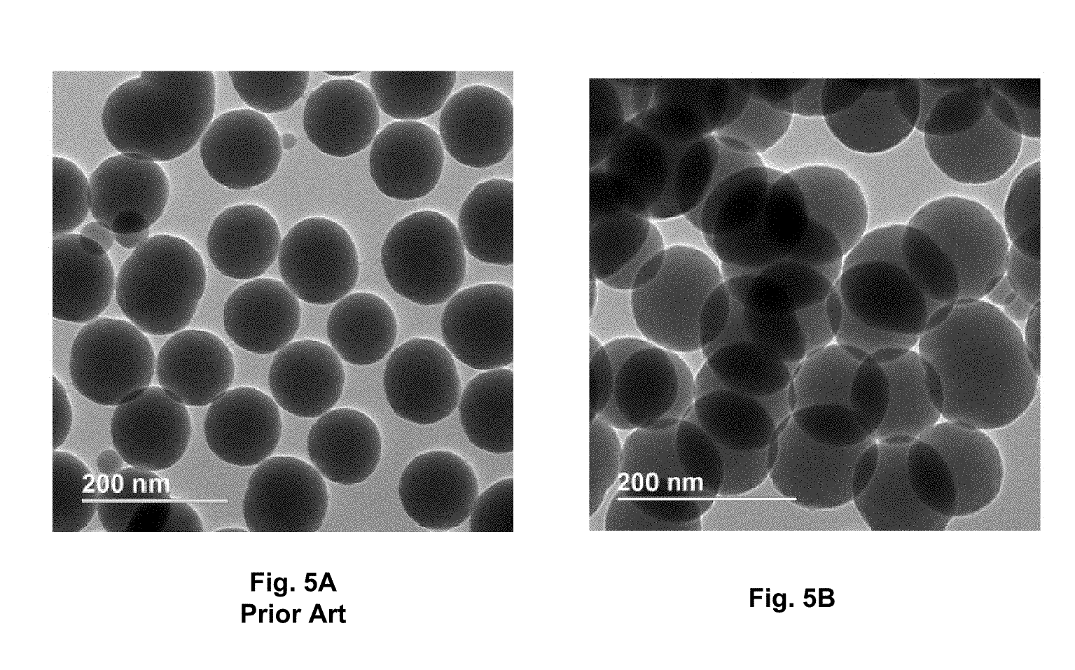

FIG. 5A provides a photograph of conventional silica fillers prior to surface treatment. FIG. 5B provides a photograph of a double-layer surface modification to a silica filler, in accordance with an embodiment of the present invention.

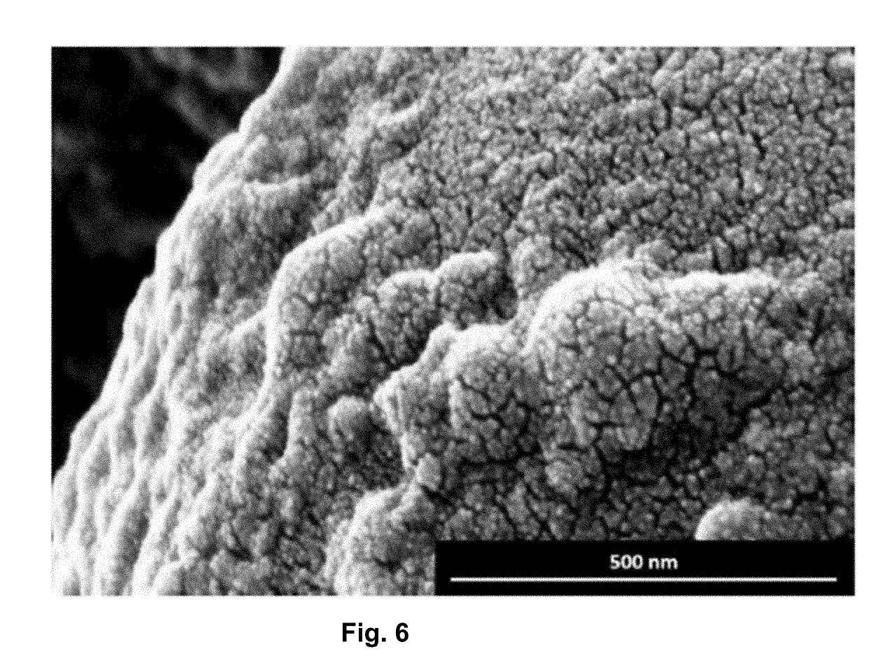

FIG. 6 provides a photograph of a polysiloxane coated silica filler in accordance with an exemplary embodiment of the present invention.

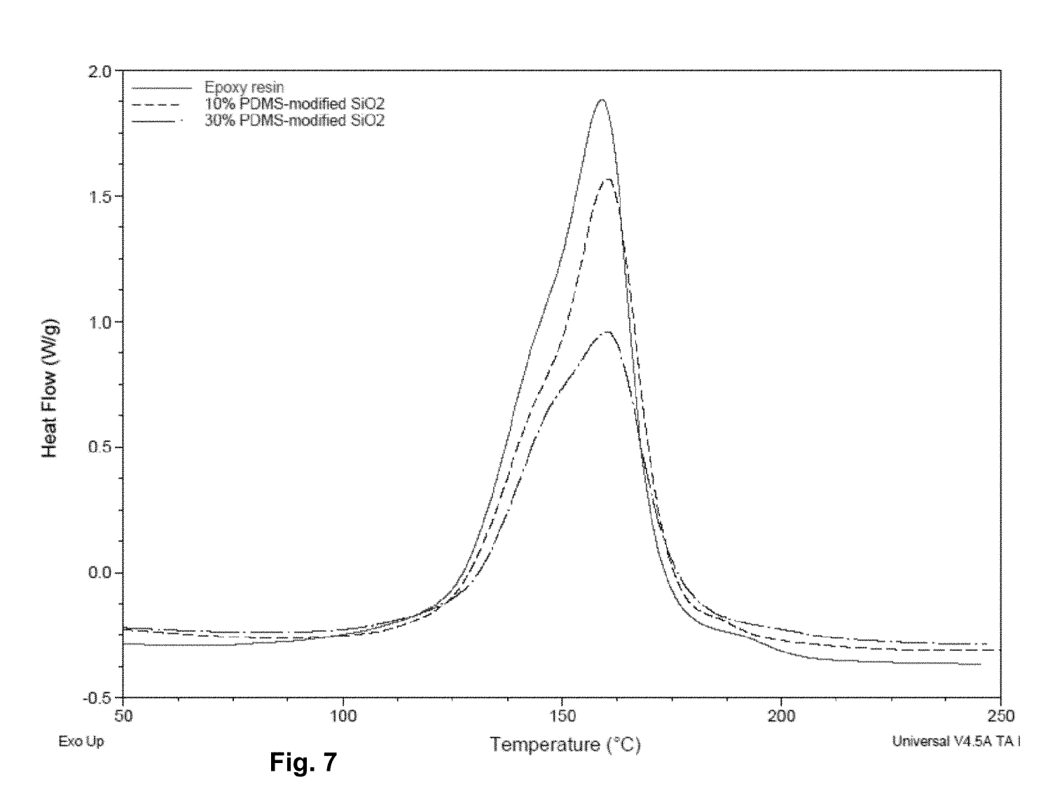

FIG. 7 provides a plot of heat flow (W/g) versus temperature (° C.) and shows that the presence of polysiloxanes does not significantly affect the curing profile of the underfill.

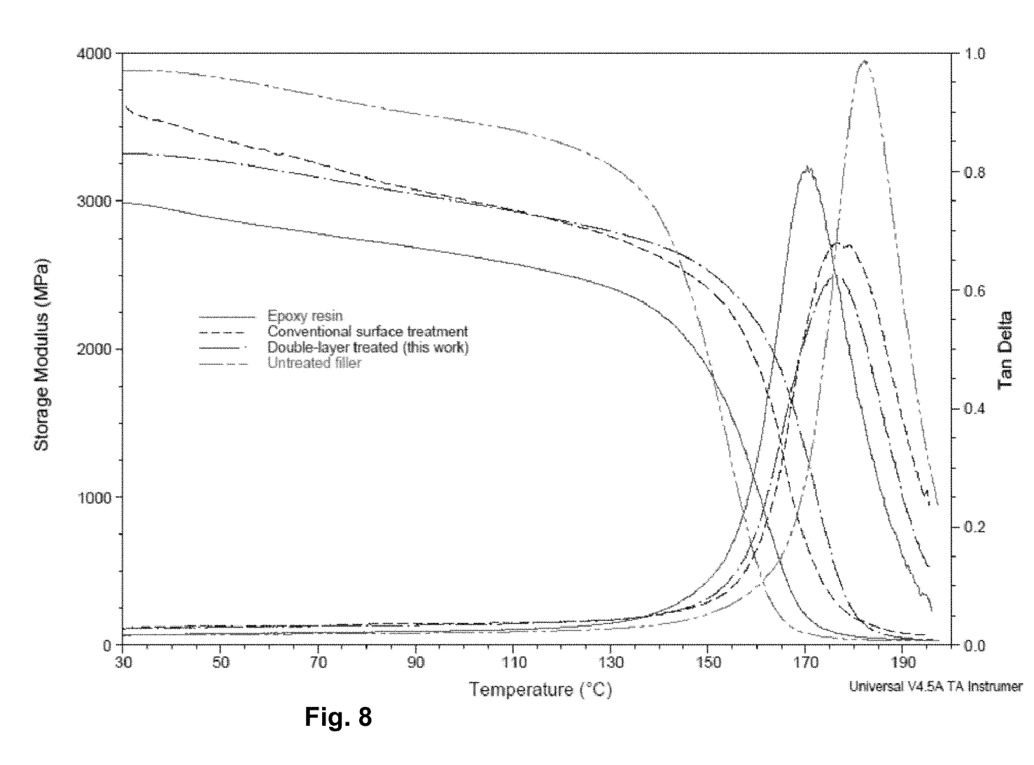

FIG. 8 provides a plot of storage modulus versus temperature for an epoxy resin, a conventional surface treated silica, a double-layered surface treated silica in accordance with an embodiment of the invention, and an untreated silica.

As shown in FIG. 8, as compared to with untreated or conventionally treated fillers at the same loading (20 wt. %), the double-layer treated filler with polysiloxane in accordance with an embodiment of the present invention shows reduced modulus below the glass transition temperature (Tg).

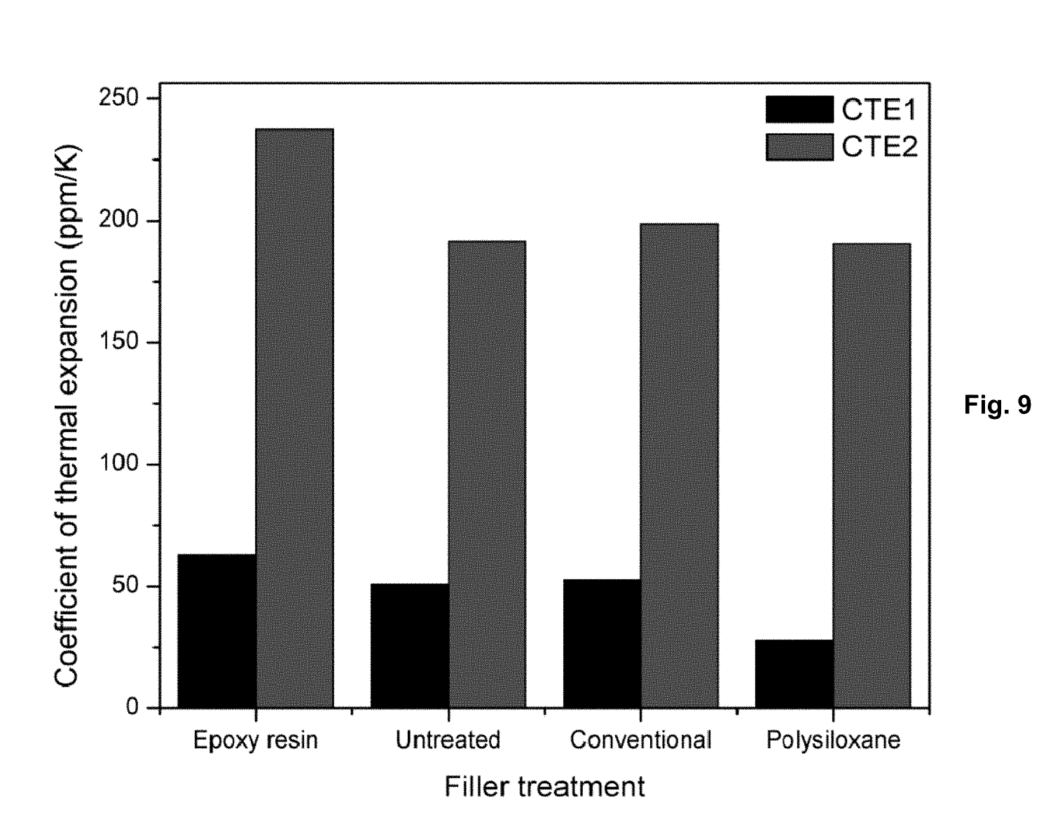

As shown in FIG. 9, both CTE1 and CTE2 are reduced with polysiloxane treated silica fillers in accordance with an embodiment of the present invention.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way. Instead, it is intended that the invention is defined by the claims appended hereto.

What is claimed is:

1. A filler comprising:
a silica core;
a first layer in communication with the core, the first layer comprising a first material;
a second layer in communication with the first layer, the second layer comprising a second material different than the first material,
wherein the second layer decreases the coefficient of thermal expansion of the filler and decreases the composite modulus of the filler as compared to a filler without the second layer.

2. The filler of claim 1, wherein the first layer comprises silane.

3. The filler of claim 1, wherein the second layer comprises polysiloxane.

4. The filler of claim 1, wherein the filler comprises an amorphous silica nanosphere.

5. The filler of claim 1, where in the second layer is covalently bonded to the first layer.

6. The filler of claim 1, wherein the second layer increases the glass transition temperature of the filler as compared to a filler without the second layer.

7. The filler of claim 1, wherein the filler has a coefficient of thermal expansion between about 20 ppm/K and about 40 ppm/K.

8. The filler of claim 7, wherein the filler has a coefficient of thermal expansion between about 25 ppm/K and about 30 ppm/K.

9. The filler of claim 1, wherein the first layer is present in the filler at about 0.75-1.5 wt. %.

10. The filler of claim 1, wherein the second layer is present in the filler at about 0.5-1.0 wt. %.

11. A method of making a filler comprising a silica core layer, a first layer, and a second layer, the method comprising:
coating the silica core with the first layer, the first layer comprising a first material; and
coating the first layer with the second layer, the second layer comprising a second material different than the first material,
wherein coating the first layer with the second layer decreases the coefficient of thermal expansion of the filler and decreases the composite modulus of the filler.

12. The method of claim 11, wherein the first layer comprises silane.

13. The method of claim 11, wherein the second layer comprises polysiloxane.

14. The method of claim 11, wherein coating the first layer with the second layer results in covalent bonds between the first and second layer.

15. The method of claim 11, wherein coating the first layer with the second layer increases the glass transition temperature of the filler.

16. The method of claim 11, wherein the filler has a coefficient of thermal expansion between about 25 ppm/K and about 30 ppm/K.

17. The method of claim 11, wherein the first layer is present in the filler at about 0.75-1.5 wt. %.

18. The method of claim 11, wherein the second layer is present in the filler at about 0.5-1.0 wt. %.

19. A filler comprising:
an amorphous silica nanosphere core;
a first layer in communication with the core, the first layer comprising silane;
a second layer covalently bonded to the first layer, the second layer comprising polysiloxane,
wherein the filler has a coefficient of thermal expansion of about 20 ppm/K to about 40 ppm/K.

20. The filler of claim 19, wherein the filler has a coefficient of thermal expansion of between about 25 ppm/K and about 30 ppm/K.
